(19) United States
(12) Patent Application Publication
(10) Pub. No.: US 2011/0232741 A1
(43) Pub. Date: Sep. 29, 2011

(54) SILICON SOLAR CELL

(75) Inventors: TING FANG, TAINAN (TW); KANG-CHENG LIN, TAIPEI COUNTY (TW)

(73) Assignee: MOTECH INDUSTRIES INC., New Taipei City (TW)

(21) Appl. No.: 13/028,503

(22) Filed: Feb. 16, 2011

(30) Foreign Application Priority Data
Mar. 29, 2010 (TW) 099109475

(51) Int. Cl. H01L 31/0224

(52) U.S. Cl. 136/256

(57) ABSTRACT

The present invention discloses a silicon solar cell including a silicon crystal, an emitter, a conductive layer, and a first metal electrode. The silicon crystal has at least one through hole formed thereon. The emitter covers at least the silicon crystal and an inner surface of the through hole on the silicon crystal; the conductive layer covers at least a portion of the emitter that is located on the inner surface of the through hole; and the first metal electrode is located in the through hole on the silicon crystal and is electrically connected at least to the conductive layer.

### FIELD OF THE INVENTION

The present invention relates to a silicon solar cell, and more particularly to a silicon solar cell having a conductive layer provided between an emitter and a metal electrode thereof.

### BACKGROUND OF THE INVENTION

The currently available back-contact solar cell is a cell structure capable of reducing light blocking by front metal material to thereby increase the photocurrent. However, in the back-contact solar cell structure, the metal slurry tends to burn through the emitter and cause serious current leakage, which would result in lowered open-circuit voltage and fill factors and might also bring the problem of reduced module reliability.

### SUMMARY OF THE INVENTION

An object of the present invention is to provide a silicon solar cell which is characterized in a conductive layer provided between an emitter and a metal electrode of the solar cell to overcome the problems in the conventional structure.

According to another object of the present invention, the silicon solar cell according to the present invention includes a silicon crystal, an emitter, a conductive layer, and a first metal electrode. The silicon crystal has at least one through hole formed thereon. The emitter covers at least the silicon crystal and an inner surface of the through hole. The conductive layer covers a portion of the emitter located on the inner surface of the through hole and covers part of the emitter located on a top surface and a bottom surface of the silicon crystal. The first metal electrode is located in the through hole and is at least electrically connected to the conductive layer. The silicon solar cell further includes an anti-reflection layer which covers another portion of the emitter and the conductive layer located on the top surface of the silicon crystal.

With the aforementioned description, the silicon solar cell according to the present invention has at least one or more of the following advantages:

(1) The conductive layer of the silicon solar cell not only increases the doping concentration of the emitter, but also provides the function of isolating the first metal electrode from the emitter.

(2) The conductive layer of the silicon solar cell not only increases the fill factors and shunt impedance, but also increases the adhesion between the first metal electrode and the emitter.

(3) The silicon solar cell of the present invention can effectively eliminate current leakage to enable upgraded photoelectric conversion efficiency.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic sectional view of a silicon solar cell according to the first embodiment of the present invention;

FIG. 2 is a schematic sectional view of a silicon solar cell according to the second embodiment of the present invention; and

FIG. 3 illustrates the preparation of the silicon solar cell according to the first embodiment of the present invention.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

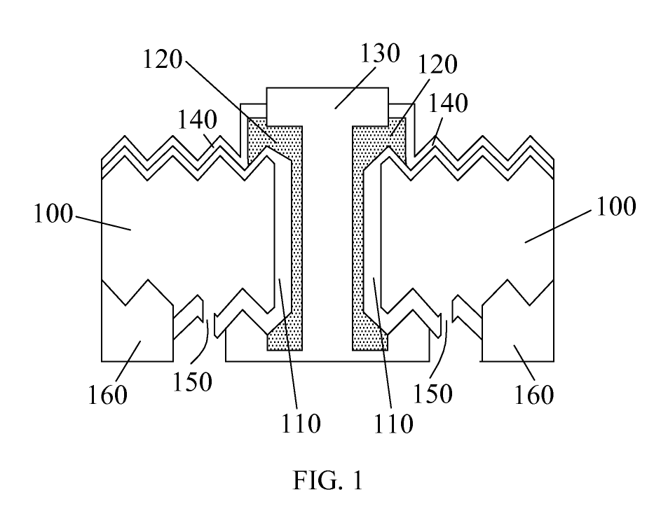

Please refer to FIG. 1 that is a schematic sectional view of a silicon solar cell according to the first embodiment of the present invention. As shown, the silicon solar cell includes a silicon crystal 100, an emitter 110, a conductive layer 120, and a first metal electrode 130. The silicon crystal 100 has at least one through hole formed thereon. The emitter 110 covers a top surface of the silicon crystal 100, an inner surface of the through hole on the silicon crystal 100, and part of a bottom surface of the silicon crystal 100. The conductive layer 120 covers a portion of the emitter 110 that is located on the inner surface of the through hole and a part of other portions of the emitter 110 that are located on the top surface and the bottom surface of the silicon crystal 100. The first metal electrode 130 is located in the through hole on the silicon crystal 100, and is electrically connected at least to the conductive layer 120 for conducting current. The conductive layer 120 and the emitter 110 have the same polarity. The silicon solar cell further includes a second metal electrode 160 located at the bottom of the silicon crystal 100. For a p-type silicon crystal, the first metal electrode 130 is a negative pole while the second metal electrode 160 is a positive pole.

The conductive layer 120 can be formed by coating or spraying. The conductive layer 120 is doped with an element from group 5A or group 3A, which can be, for example, phosphorus or boron, to thereby have the property of reducing the sheet resistance of the emitter 110 in contact with the conductive layer 120 and strengthening the adhesion between the emitter 110 and the first metal electrode 130. In addition, the silicon solar cell further includes an anti-reflection layer 140, which covers another portion of the emitter 110 and the conductive layer 120 that are located on the top surface of the silicon crystal 100. Moreover, the emitter 110 on the bottom surface of the silicon crystal 100 is further provided with an insulation structure 150, which is located between the first metal electrode 130 and the second metal electrode 160.

The silicon crystal can be an n-type or a p-type polycrystalline silicon or monocrystalline silicon. In the illustrated first preferred embodiment, the silicon solar cell structure is a metal-wrap-through (MWT) back-contact solar cell to avoid current shunting.

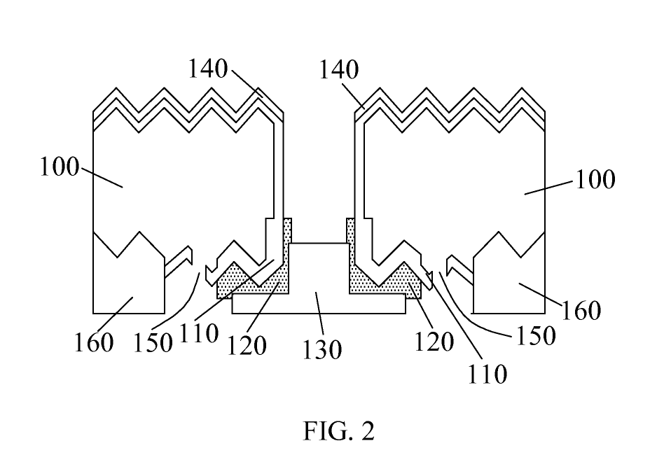

Please refer to FIG. 2 that is a schematic sectional view of a silicon solar cell according to the second embodiment of the present invention. As shown, the silicon solar cell in the second embodiment includes a silicon crystal 100, an emitter 110, a conductive layer 120, and a first metal electrode 130. The silicon crystal 100 has at least one through hole formed thereon. The emitter 110 covers a top surface of the silicon crystal 100, an inner surface of the through hole on the silicon crystal 100, and part of a bottom surface of the silicon crystal 100. The conductive layer 120 covers a portion of the emitter 110 that is located on the inner surface of the through hole and part of another portion of the emitter 110 that is located on the bottom surface of the silicon crystal 100. The first metal electrode 130 is located in the through hole on the silicon crystal 100, and is electrically connected at least to the conductive layer 120 for conducting current. The conductive layer 120 and the emitter 110 have the same polarity. The silicon solar cell further includes a second metal electrode 160 located at a bottom of the silicon crystal 100. For a p-type silicon crystal, the first metal electrode 130 is a negative pole while the second metal electrode 160 is a positive pole. The second embodiment is different from the first embodiment in that the first metal electrode 130 in the second embodiment is located in the through hole at a bottom thereof, while the first metal electrode 130 in the first embodiment is located in the through hole to extend from a top to a bottom of the through hole. While the silicon solar cell in the first embodiment is configured as a MWT back-contact silicon solar cell, the silicon solar cell in the second embodiment is configured as an emitter-wrap-through (EWT) back-contact silicon solar cell.

Again, in the second embodiment, the conductive layer 120 can be formed by coating or spraying, and is doped with a 5A or 3A group element, which can be, for example, phosphorus or boron, to thereby obtaining the property of reducing the sheet resistance of the emitter 110 in contact with the conductive layer 120 and strengthening the adhesion between the emitter 110 and the first metal electrode 130. In addition, the silicon solar cell further includes an anti-reflection layer 140, which covers at least the emitter 110 located on the top surface of the silicon crystal 100. Moreover, the emitter 110 on the bottom surface of the silicon crystal 100 is further provided with an insulation structure 150, which is located between the first metal electrode 130 and the second metal electrode 160.

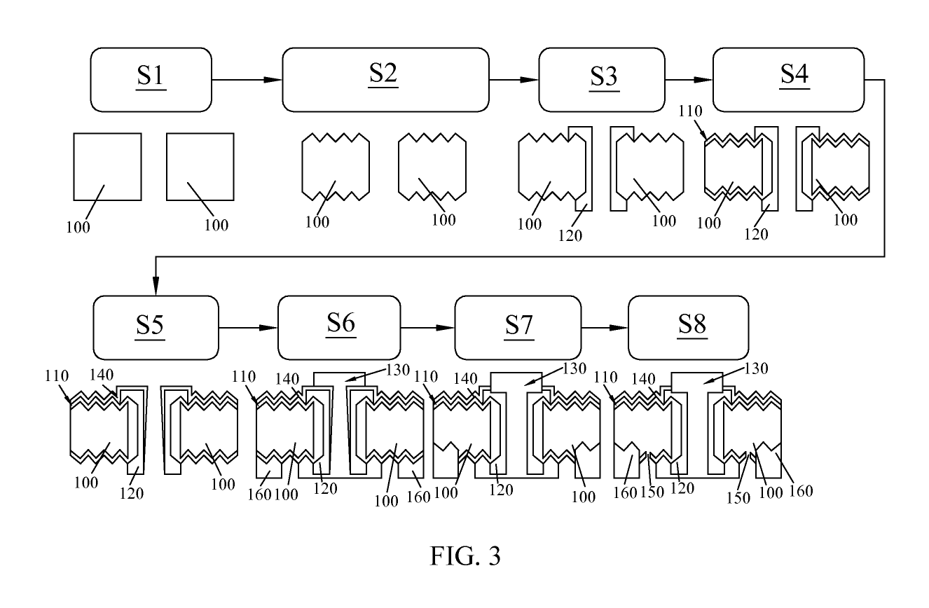

Please refer to FIG. 3 that illustrates the preparation of the silicon solar cell according to the first embodiment of the present invention. As shown in FIG. 3, the silicon solar cell is prepared with the following steps:

Step S1: Forming at least one through hole on a silicon crystal 100 by way of laser drilling. However, it is understood the through hole can be formed in other ways without being limited to the laser drilling;

Step S2: using a chemical substance to etch the silicon crystal 100 while cleaning the same, so that the silicon crystal 100 has a coarsened surface;

Step S3: coating a conducting layer 120 on an inner surface of the through hole on the silicon crystal 100;

Step S4: forming an emitter 110 on a top surface and a bottom surface of the silicon crystal 100 as well as on the inner surface of the through hole;

Step S5: producing an anti-reflection layer 140 to cover portions of the emitter 110 and the conductive layer 120 that are located on the top surface of the silicon crystal 100;

Step S6: coating the first metal electrode 130 on the inner surface of the through hole on the silicon crystal 100, and on a part of the top surface and the bottom surface of the silicon crystal 100; also coating the second metal electrode 160 on another part of the bottom surface of the silicon crystal 100;

Step S7: implementing a quenching and high-temperature tempering process on the whole silicon solar cell, so as to remove a portion of the anti-reflection layer 140 that is located between the first metal electrode 130 and the conductive layer 120, allowing the first metal electrode 130 to electrically connect to the conductive layer 120; and

Step S8: cutting apart the portion of the emitter 110 that is located on the bottom surface of the silicon crystal 100 by way of laser or etching, so that an insulation structure 150 is formed on the emitter 110 between the first metal electrode 130 and the second metal electrode 160.

After the aforementioned eight steps are performed, the silicon solar cell according to the present invention is accomplished. However, it is noted the steps above are used to prepare only a MWT back-contact solar cell according to the first embodiment of the present invention.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A silicon solar cell, comprising:
a silicon crystal comprising at least one through hole formed thereon;
an emitter at least covering the silicon crystal and covering an inner surface of the at least one through hole on the silicon crystal;
a conductive layer at least covering a portion of the emitter, the portion located on the inner surface of the at least one through hole; and
a first metal electrode located in the at least one through hole on the silicon crystal and at least electrically connected to the conductive layer.

2. The silicon solar cell as claimed in claim 1, further comprising an anti-reflection layer at least covering another portion of the emitter located on a top surface of the silicon crystal.

3. The silicon solar cell as claimed in claim 1, wherein the conductive layer is doped with at least one element from group 5A or group 3A.

4. The silicon solar cell as claimed in claim 1, wherein the silicon crystal is selected from the group consisting of n-type polycrystalline silicon, n-type monocrystalline silicon, p-type polycrystalline silicon, and p-type monocrystalline silicon.

5. The silicon solar cell as claimed in claim 1, further comprising a second metal electrode located at a bottom of the silicon crystal.
